(19) United States
(12) Patent Application Publication
(10) Pub. No.: US 2015/0068703 A1
(43) Pub. Date: Mar. 12, 2015

(54) THERMAL MANAGEMENT SYSTEM AND METHOD OF ASSEMBLING THE SAME

(71) Applicants: GE Aviation Systems LLC, Grand Rapids, MI (US); General Electric Company, Schenectady, NY (US)

(72) Inventors: Hendrik Pieter Jacobus de Bock, Clifton Park, NY (US); Jonathan Mark Dunsdon, Glenville, NY (US); Michel Engelhardt, Bohemia, NY (US)

(73) Assignees: GE Aviation Systems LLC, Grand Rapids, MI (US); General Electric Company, Schenectady, NY (US)

(21) Appl. No.: 14/020,506

(22) Filed: Sep. 6, 2013

(51) Int. Cl. H05K 7/20

(52) U.S. Cl. CPC H05K 7/20854; H05K 7/2039; H05K 2007/20527
USPC 165/41; 165/104.26

(57) ABSTRACT

A thermal management system for cooling a heat source onboard an aircraft that has a frame and a skin coupled to the frame such that the skin has a first segment and a second segment includes a first network of heat pipes coupled in conductive heat transfer with the heat source and the first segment of skin. The first network of heat pipes is configured to heat the first segment of skin using heat from the heat source. The thermal management system further includes a second network of heat pipes coupled in conductive heat transfer with the heat source and the second segment of skin. The second network of heat pipes is configured to heat the second segment of skin using heat from the heat source. The thermal management system is configured to selectively deactivate the first network of heat pipes and the second network of heat pipes.

### BACKGROUND

The subject matter described herein relates generally to thermal management systems and, more particularly, to a thermal management system for cooling a heat source onboard an aircraft.

Many aircraft utilize electronic systems that generate significant amounts of heat, and the heat should be dissipated from the electronic systems in order to keep the systems functioning properly. At least some known cooling systems for dissipating heat from the electronics on an aircraft include forced-air cooling systems (e.g., cooling systems that blow air over the electronics using ductwork) or forced-liquid cooling systems (e.g., cooling systems that channel liquid coolant through a cooling circuit using a pump). However, in some circumstances, these known cooling systems are ineffective at cooling the electronics and make inefficient use of the heat generated by the electronics.

### BRIEF DESCRIPTION

In one aspect, a thermal management system for cooling a heat source onboard an aircraft is provided. The aircraft has a frame and a skin coupled to the frame such that the skin includes a first segment and a second segment. The thermal management system includes a first network of heat pipes coupled in conductive heat transfer with the heat source and the first segment of the skin. The first network of heat pipes is configured to heat the first segment of the skin using heat from the heat source. The thermal management system further includes a second network of heat pipes coupled in conductive heat transfer with the heat source and the second segment of the skin. The second network of heat pipes is configured to heat the second segment of the skin using heat from the heat source. The thermal management system is configured to selectively deactivate the first network of heat pipes and the second network of heat pipes.

In another aspect, a method of assembling a thermal management system for cooling a heat source onboard an aircraft is provided. The aircraft includes a frame and a skin coupled to the frame such that the skin has a first segment and a second segment. The method includes coupling a first network of heat pipes in conductive heat transfer with the heat source and the first segment of the skin. The first network of heat pipes is configured to heat the first segment of the skin using heat from the heat source. The method further includes coupling a second network of heat pipes in conductive heat transfer with the heat source and the second segment of the skin. The second network of heat pipes is configured to heat the second segment of the skin using heat from the heat source. The method also includes coupling a processing unit to the first network of heat pipes and the second network of heat pipes. The processing unit is configured to selectively deactivate the first network of heat pipes and the second network of heat pipes.

In another aspect, a thermal management system for cooling a heat source onboard an aircraft having a frame and a skin coupled to the frame is provided. The thermal management system includes a network of heat pipes configured to transfer heat from the heat source to the skin by conductive heat transfer between adjacent heat pipes.

### DRAWINGS

These and other features, aspects, and advantages of the present disclosure will become better understood when the following detailed description is read with reference to the accompanying drawings in which like characters represent like parts throughout the drawings, wherein:

FIG. 1 is a perspective view of an exemplary aircraft;

FIG. 2 is a partially cut out view of a wing of the aircraft shown in FIG. 1;

FIG. 3 is a block diagram of an exemplary thermal management system for cooling avionics onboard the aircraft shown in FIG. 1;

FIG. 4 is a schematic side view of a heat pipe that may be used in the thermal management system shown in FIG. 3;

FIG. 5 is schematic cross-sectional view of the heat pipe shown in FIG. 4 taken along plane 5-5 of FIG. 4; and

FIG. 6 is a schematic plan view of the aircraft shown in FIG. 1 including an embodiment of the thermal management system shown in FIG. 3.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The embodiments disclosed herein facilitate effectively cooling heat sources onboard an aircraft. The embodiments further facilitate cooling the electronic systems of an aircraft, thereby enabling the use of more powerful electronic systems onboard the aircraft. The devices, systems, and methods disclosed herein also facilitate increasing the reliability of functioning heat sources (such as electronic systems) onboard an aircraft by preventing them from overheating. The devices, systems, and methods further facilitate cooling heat sources onboard an aircraft using less electricity, thereby being less of an electrical load on the power supply of the aircraft. Additionally, the embodiments disclosed herein facilitate utilizing the undesired heat produced by existing heat sources onboard an aircraft to alter the infrared signature of the aircraft by redistributing the undesired heat to exterior surfaces of the aircraft prior to dissipating the heat from the aircraft, thereby heating the exterior surfaces of the aircraft using less centerline electrical power than would electrically powered heating elements dedicated for use in heating the exterior surfaces of the aircraft. The embodiments also facilitate providing a thermal management system that weighs less, e.g., in the absence of associated ductwork, pumps, larger quantities of liquid coolant, etc., thereby enabling the aircraft to weigh less and be more fuel efficient. The devices, systems, and methods disclosed herein further facilitate improving the fuel efficiency of an aircraft by transferring heat to the fuel in order to preheat the fuel for improving combustion performance.

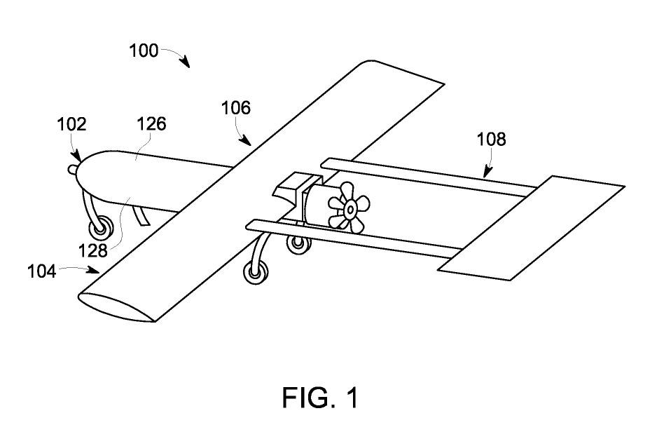

FIG. 1 is a perspective view of an aircraft 100. In the exemplary embodiment, aircraft 100 is an unmanned aerial vehicle (UAV) that has a fuselage 102, a first wing 104, a second wing 106, and a tail 108. In other embodiments, aircraft 100 may be a manned aircraft without departing from the scope of this invention.

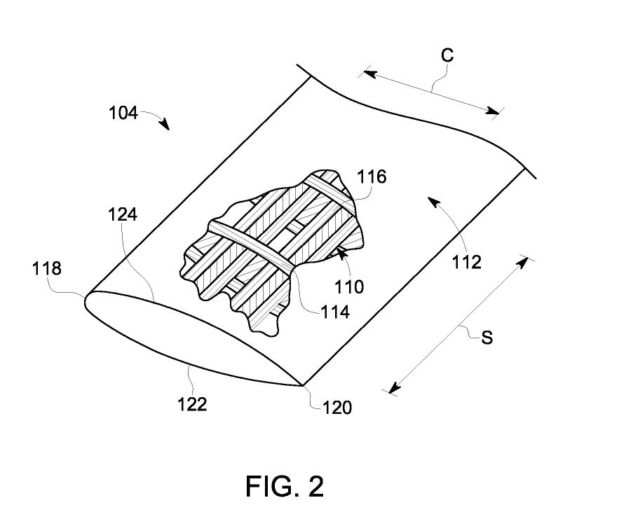

FIG. 2 is a partially cut out view of first wing 104. While first wing 104 is described in more detail below, it should be noted that second wing 106 is constructed in the same manner as first wing 104. In the exemplary embodiment, aircraft 100 has a frame 110 and a skin 112 that are both fabricated from a metallic material, e.g., without limitation, an aluminum material. On first wing 104, frame 110 includes an arrangement of ribs 114 and spars 116 that support skin 112 such that skin 112 takes on an airfoil-type shape. The airfoil-type shape defines a leading edge (or surface) 118, a trailing edge (or surface) 120, a pressure side 122 extending from leading edge 118 to trailing edge 120, and a suction side 124 extending from leading edge 118 to trailing edge 120 opposite pressure side 122. In this manner, first wing 104 has a spanwise dimension S and a chordwise dimension C.

Ribs 114 extend in the chordwise dimension C and are spaced apart from one another in the spanwise dimension S, and spars 116 extend in the spanwise dimension S and are spaced apart from one another in the chordwise dimension C. During flight, air flows over skin 112 of first wing 104 to provide lift for aircraft 100. Notably, other embodiments of frame 110 may have any suitable arrangement of structural members associated with first wing 104, and other embodiments of skin 112 may define any suitable shape of first wing 104. Moreover, it should be noted that frame 110 also supports skin 112 of fuselage 102, tail 108, and other suitable regions of aircraft 100, e.g., frame 110 supports skin 112 such that fuselage 102 takes on a generally tubular shape having a top 126 and a bottom 128, which are shown in FIG. 1.

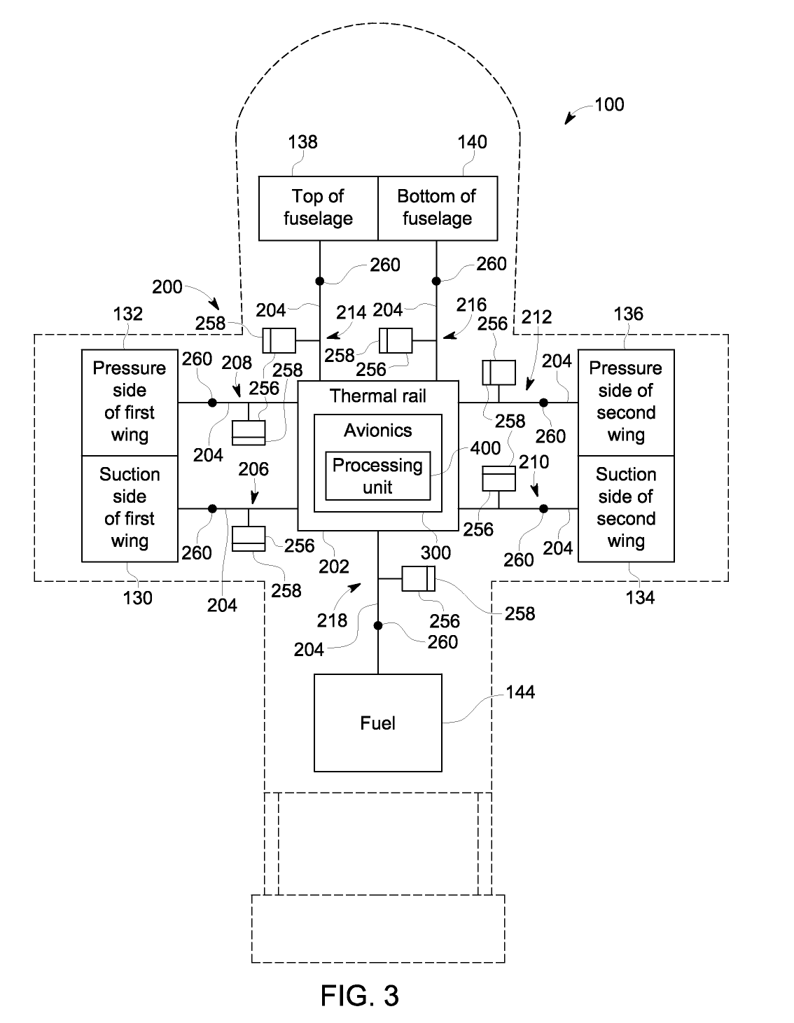

FIG. 3 is a block diagram of a thermal management system 200 for cooling avionics 300 (i.e., an electronic heat dissipating source) onboard aircraft 100. Thermal management system 200 includes a thermal rail 202 and a plurality of heat pipes 204 coupled in conductive heat transfer with thermal rail 202, as set forth in more detail below. In the exemplary embodiment, thermal rail 202 is a metal plate or rod disposed within fuselage 102, and avionics 300 are coupled in conductive heat transfer with thermal rail 202 such that heat is transferrable from avionics 300 to thermal rail 202 via conduction. Notably, thermal rail 202 may be any suitable shape, may be fabricated from any suitable conductive material, and may be coupled to avionics 300 in any suitable manner that enables thermal rail 202 to function as described herein.

In the exemplary embodiment, heat pipes 204 are arranged as follows. A first network 206 of heat pipes 204 is coupled in conductive heat transfer with a first segment 130 of skin 112 (e.g., suction side 124 of first wing 104). A second network 208 of heat pipes 204 is coupled in conductive heat transfer with a second segment 132 of skin 112 (e.g., pressure side 122 of first wing 104). A third network 210 of heat pipes 204 is coupled in conductive heat transfer with a third segment 134 of skin 112 (e.g., suction side 124 of second wing 106). A fourth network 212 of heat pipes 204 is coupled in conductive heat transfer with a fourth segment 136 of skin 112 (e.g., pressure side 122 of second wing 106). A fifth network 214 of heat pipes 204 is coupled in conductive heat transfer with a fifth segment 138 of skin 112 (e.g., top 126 of fuselage 102). A sixth network 216 of heat pipes 204 is coupled in conductive heat transfer with a sixth segment 140 of skin 112 (e.g., bottom 128 of fuselage 102). A seventh network 218 of heat pipes 204 is coupled in conductive heat transfer with fuel 144 contained in a fuel tank, a fuel line, or other suitable fuel-containing structure of aircraft 100.

Notably, each network 206, 208, 210, 212, 214, 216, 218 may be made up of any suitable number of heat pipes 204, i.e., one or more heat pipes 204, arranged in any suitable manner. Additionally, thermal management system 200 may include any suitable number of networks coupled to any suitable heat source(s) of aircraft 100 in any suitable manner that facilitates dissipating heat from the heat source(s) as described herein. In one alternative embodiment, heat pipes 204 may be coupled directly to avionics 300, thereby eliminating thermal rail 202 from thermal management system 200. Moreover, in other embodiments, thermal management system 200 may include any suitable heat moving structures that function in lieu of, or in conjunction with, heat pipes 204 to facilitate enabling the dissipation of heat from heat source(s) onboard aircraft 100 as described herein.

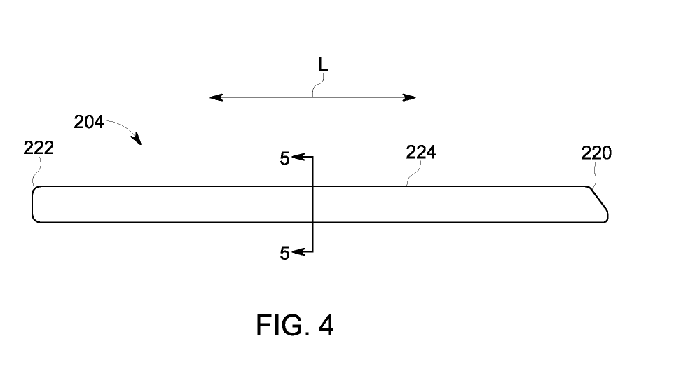

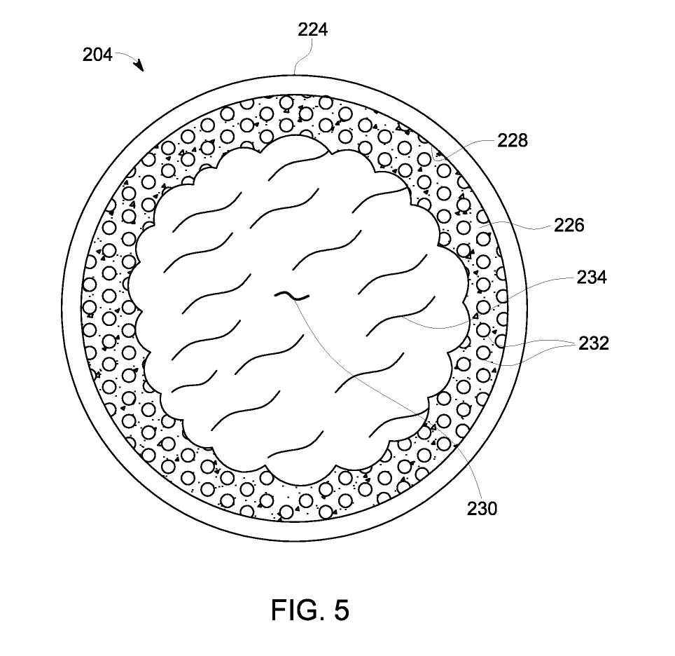

FIGS. 4 and 5 are schematic side and cross-sectional views of an exemplary heat pipe 204 of thermal management system 200. In the exemplary embodiment, heat pipe 204 is a two-phase, capillary device having a sealed first end 220, a sealed second end 222, and a hollow body 224 extending from first end 220 to second end 222 along a lengthwise dimension L of heat pipe 204. A permeable membrane 226 lines an interior surface 228 of body 224 to define an elongate central void 230 extending between first end 220 and second end 222. A working liquid 232 is disposed within body 224 in a quantity sufficient to permeate at least a portion of membrane 226 without preventing gas from flowing lengthwise along central void 230.

In the exemplary embodiment, heat pipe 204 is fabricated from an aluminum material. In other embodiments, however, heat pipe 204 may be fabricated from any suitable materials such as, for example, a copper material or a titanium material. Additionally, while working liquid 232 may be any suitable liquid, working liquid 232 is a butane liquid or an ammonia liquid in the exemplary embodiment. Moreover, in some suitable embodiments, heat pipe 204 may be configured to function as a structural member of aircraft 100. For example, in the exemplary embodiment of aircraft 100, frame 110 of first wing 104, second wing 106, and/or fuselage 102 includes structural members, e.g., ribs 114 and spars 116, fabricated from an extruded aluminum material such that each structural member has a hollow core. In this manner, at least one of the structural members may be utilized as heat pipe 204 by adding membrane 226 and working liquid 232 into the hollow core of the structural member. In other embodiments, however, heat pipe 204 may not be configured to function as a structural member of aircraft 100.

In one exemplary function of heat pipe 204, heat pipe 204 is heated near first end 220, and working liquid 232 permeating membrane 226 within heat pipe 204 near first end 220 vaporizes such that a vapor 234 travels toward second end 222 along central void 230. Because heat pipe 204 is cooler near second end 222, vapor 234 condenses near second end 222, thereby warming body 224 near second end 222. The condensate, i.e., working liquid 232, that results near second end 222 is then wicked toward first end 220 via capillaries in membrane 226 such that the working liquid 232 is again heated near first end 220. In this manner, heat pipe 204 maintains a cycle of vaporizing and condensing working liquid 232 to transfer heat along its length L, thereby providing heat spreading performance for its weight. Notably, in other modes of operation, heat pipe 204 may be heated at any suitable location along its length L to transfer heat to any other suitable location along its length L, as opposed to being heated near first end 220 for transferring heat toward second end 222.

Because the size of the particles that make up membrane 226 affects the size of the capillaries within membrane 226 and, therefore, the wicking strength of membrane 226, the particles of membrane 226 in the exemplary embodiment are made small enough that, when working liquid 232 in membrane 226 is under the influence of an external force (such as gravity) that opposes the intended lengthwise direction of wicking, membrane 226 continues to effectively wick working liquid 232 toward the portion of heat pipe 204 that is being heated. In that regard, heat pipe 204 is configured to wick working liquid 232 against multiple times the force of gravity such that only a negligible difference in heat transfer capability is experienced as a result of changes to the orientation or altitude of heat pipe 204. More specifically, in the exemplary embodiment, the capillary structure of membrane 226 is made small enough to wick working liquid 232 against forces as strong as five to ten times the force of gravity, thereby enabling heat pipe 204 to effectively transfer heat along its length L in any orientation of heat pipe 204 and at altitudes of between 45,000 and 65,000 feet above sea level (or any other suitable altitude outside of such range).

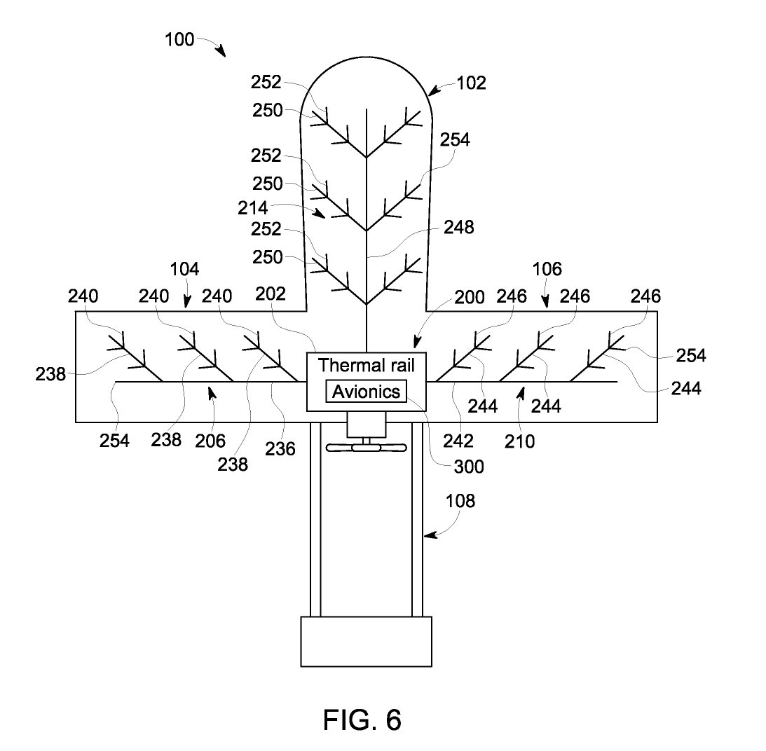

FIG. 6 is a schematic plan view of aircraft 100 having an embodiment of thermal management system 200. In the embodiment of FIG. 6, thermal rail 202 (and, therefore, avionics 300) is located within fuselage 102, and networks 206, 208, 210, 212, 214, 216, 218 of heat pipes 204 extend from thermal rail 202 throughout aircraft 100, as set forth in more detail below. More specifically, first network 206 is arranged in a herringbone-type configuration as follows. A first primary heat pipe 236 is coupled in conductive heat transfer with thermal rail 202 and extends into first wing 104. A plurality of first secondary heat pipes 238 extend obliquely from first primary heat pipe 236 within first wing 104. A plurality of first tertiary heat pipes 240 extend obliquely from each first secondary heat pipe 238 within first wing 104. First primary heat pipe 236, first secondary heat pipes 238, and/or first tertiary heat pipes 240 are coupled in conductive heat transfer with first segment 130 of skin 112 on suction side 124 of first wing 104. Notably, this embodiment of thermal management system 200 may also include second network 208 of heat pipes 204 (as shown in FIG. 3), and second network 208 of heat pipes 204 may be arranged in a herringbone-type configuration extending from thermal rail 202 into first wing 104 in a manner similar to that of first network 206, with at least one heat pipe 204 of second network 208 being coupled in conductive heat transfer with second segment 132 of skin 112 on pressure side 122 of first wing 104.

Similarly, third network 210 is also arranged in a herringbone-type configuration as follows. A third primary heat pipe 242 is coupled in conductive heat transfer with thermal rail 202 and extends into second wing 106. A plurality of third secondary heat pipes 244 extend obliquely from third primary heat pipe 242 within second wing 106. A plurality of third tertiary heat pipes 246 extend obliquely from each third secondary heat pipe 244 within second wing 106. Third primary heat pipe 242, third secondary heat pipes 244, and/or third tertiary heat pipes 246 are coupled in conductive heat transfer with third segment 134 of skin 112 on suction side 124 of second wing 106. Notably, this embodiment of thermal management system 200 may also include fourth network 212 of heat pipes 204 (as shown in FIG. 3), and fourth network 212 of heat pipes 204 may be arranged in a herringbone-type configuration extending from thermal rail 202 into second wing 106 in a manner similar to that of third network 210, with at least one heat pipe 204 of fourth network 212 being coupled in conductive heat transfer with skin 112 on pressure side 122 of second wing 106.

Additionally, fifth network 214 is also arranged in a herringbone-type configuration as follows. A fifth primary heat pipe 248 is coupled in conductive heat transfer with thermal rail 202 within fuselage 102. A plurality of fifth secondary heat pipes 250 extend obliquely from fifth primary heat pipe 248 within fuselage 102. A plurality of fifth tertiary heat pipes 252 extend obliquely from each fifth secondary heat pipe 250 within fuselage 102. Fifth primary heat pipe 248, fifth secondary heat pipes 250, and/or fifth tertiary heat pipes 252 are coupled in conductive heat transfer with skin 112 on top 126 of fuselage 102. Notably, this embodiment of thermal management system 200 may also include sixth network 216 of heat pipes 204 (as shown in FIG. 3), and sixth network 216 of heat pipes 204 may be arranged in a herringbone-type configuration extending from thermal rail 202 within fuselage 102 in a manner similar to that of fifth network 214, with at least one heat pipe 204 of sixth network 216 being coupled in conductive heat transfer with skin 112 on bottom 128 of fuselage 102.

Alternatively, thermal rail 202 and avionics 300 may be located in any suitable area of aircraft 100 such as, for example, an area other than fuselage 102. Moreover, heat pipes 204 of each network 206, 208, 210, 212, 214, 216 may be arranged in any suitable manner, e.g., heat pipes 204 of each network 206, 208, 210, 212, 214, 216 may extend from thermal rail 202 in parallel to one another, may be oriented perpendicular to one another, or may extend along curvilinear paths. In some embodiments, each heat pipe 204 of each network 206, 208, 210, 212, 214, 216 may be sealed with respect to other heat pipes 204 within the same network 206, 208, 210, 212, 214, 216, i.e., each heat pipe 204 within each network 206, 208, 210, 212, 214, 216 may utilize its own distinct quantity of working liquid 232 and may be coupled (in conductive heat transfer) to other heat pipes 204 within the same network 206, 208, 210, 212, 214, 216 such that heat is transferred in series from one heat pipe 204 to another heat pipe 204 within each network 206, 208, 210, 212, 214, 216 via conduction between adjacent heat pipes 204. In other embodiments, heat pipes 204 within each network 206, 208, 210, 212, 214, 216 may be coupled in fluid communication with one another such that heat pipes 204 within each network 206, 208, 210, 212, 214, 216 share a common quantity of working liquid 232, effectively providing a single, branched heat pipe 204 for each network 206, 208, 210, 212, 214, 216. Notably, in the embodiment of FIG. 6 and other suitable embodiments, each heat pipe 204 (and, therefore, each network 206, 208, 210, 212, 214, 216 of heat pipes 204) has distal end(s) 254 and is not a continuous loop, thereby relying on two-phase, bidirectional fluid flow in order to transfer heat from the heat source, e.g., avionics 300, to the heat sink, e.g., skin 112.

During operation of aircraft 100 (which is a UAV in the exemplary embodiment), avionics 300 onboard aircraft 100 may operate a navigation system, a remote sensing system, and a propulsion system, among others systems. As such, avionics 300 are a significant electrical load for the power source onboard aircraft 100, thereby producing a significant amount of heat. However, when flying at higher altitudes, e.g., 45,000-65,000 feet above sea level, the air density is significantly less than that at sea level, meaning that the convective heat transfer coefficient that permits heat transfer to the ambient air becomes more difficult to manage for removing heat from aircraft 100.

In that regard, thermal management system 200 facilitates effectively removing heat from avionics 300 (and aircraft 100) at higher altitudes. More specifically, the heat from avionics 300 is transferred to thermal rail 202 via conduction, and thermal rail 202 transfers the heat via conduction to one or more heat pipes 204 within each network 206, 208, 210, 212, 214, 216. The heat is then transferred along each heat pipe 204 (or network 206, 208, 210, 212, 214, 216 of heat pipes 204) as set forth above. The heat is then transferred from at least one heat pipe 204 of each network 206, 208, 210, 212, 214, 216 to an associated segment 130, 132, 134, 136, 138, 140 of skin 112 via conduction, thereby heating skin 112 such that the heat generated by avionics 300 is dissipated from skin 112 by air flowing over skin 112 while aircraft 100 is in flight. In this manner, thermal management system 200 facilitates cooling avionics 300 by effectively moving the heat generated by avionics 300 to skin 112 (or other suitable exterior surface) of aircraft 100, enabling removal of the heat from aircraft 100 by ambient air flowing over skin 112 during flight.

By transferring the heat from avionics 300 to larger exterior surfaces of aircraft 100 (such as skin 112), the heat is efficiently dissipated into the ambient despite the low air density that may exist at altitude. As a result, the junction temperatures of avionics 300 are better managed, and more powerful avionics 300 may be utilized onboard aircraft 100. Moreover, because each heat pipe 204 is configured to provide effective heat transfer in any orientation of heat pipe 204 and at higher altitudes, thermal management system 200 is less affected by changes to the orientation and altitude of aircraft 100 during flight, e.g., thermal management system 200 is able to effectively remove heat from avionics 300 despite aircraft 100 flying in a banked orientation for annular patterning at 45,000-65,000 feet above sea level.

Furthermore, it may be desirable in some instances to render aircraft 100 less detectable during flight. Noting that aircraft 100 is susceptible to detection from below (via ground or sea-based systems) and from above (via satellite or spacecraft-based systems), the temperature of the land, sea, and sky typically provide thermal backdrops for detecting aircraft 100 when viewing aircraft 100 using a thermal imagery system. More specifically, because the various operating systems onboard aircraft 100 generate heat, aircraft 100 naturally takes on an infrared signature (or profile) that is different, i.e., warmer or cooler, than its land backdrop, sea backdrop, or sky backdrop, thereby making it possible to detect aircraft 100 from a thermal imagery standpoint. As such, it may be desirable to alter the infrared signature of aircraft 100 to minimize being detected. For example, in some instances, it may be desirable to heat up or cool down the exterior surfaces, e.g., skin 112, of aircraft 100 to better match the temperature of a selected backdrop of land, sea, and/or sky, effectively camouflaging aircraft 100. Moreover, in other instances, it may be desirable to render the infrared signature of aircraft 100 indiscernible or to eliminate the infrared signature of aircraft 100 altogether.

To implement these anti-detection techniques, thermal management system 200 may be further configured to utilize the heat generated by avionics 300 to alter the infrared signature of aircraft 100. Referring again to FIG. 3, thermal management system 200 may further include a processing unit 400 configured to selectively (and independently) deactivate the various networks 206, 208, 210, 212, 214, 216, 218 of heat pipes 204 from their associated heat source(s), e.g., avionics 300. As used herein, the term “deactivating” a network or any variation thereof refers to actively reducing heat transfer along the network.

To this end, in some embodiments, at least one heat pipe 204 of each network 206, 208, 210, 212, 214, 216, 218 may be a variable conductance heat pipe that is operable to deactivate its associated network 206, 208, 210, 212, 214, 216, 218 of heat pipes 204. The variable conductance heat pipe 204 would be provided with a reservoir 256 of gas, e.g., argon or helium gas, in flow communication with central void 230 such that, when the gas is heated within reservoir 256 and is permitted to exit reservoir 256, the gas expands within reservoir 256 and exits reservoir 256 to fill central void 230, thereby preventing (or inhibiting) vapor 234 from traveling along central void 230 and, therefore, deactivating the associated network 206, 208, 210, 212, 214, 216, 218 of heat pipes 204. To the contrary, when the gas within reservoir 256 is subsequently cooled, the gas contracts and reenters reservoir 256 to no longer prevent (or inhibit) vapor 234 from traveling through central void 230. Notably, reservoir 256 may be heated in any suitable manner, such as, for example, by an electric heater 258 coupled to reservoir 256.

As such, processing unit 400 may be configured to operate electric heaters 258 (or other suitable heating devices) in order to selectively (and independently) heat the gas within each reservoir 256 in order to deactivate any one or more network(s) 206, 208, 210, 212, 214, 216, 218. In other embodiments, thermal management system 200 may include a thermal switch or a bimetallic cantilever associated with each network 206, 208, 210, 212, 214, 216, 218 of heat pipes 204 to facilitate deactivating the various networks 206, 208, 210, 212, 214, 216, 218. Alternatively, thermal management system 200 may include any suitable mechanism that acts as a thermal valve of sorts for each heat pipe 204 or each network 206, 208, 210, 212, 214, 216, 218 of heat pipes 204.

Because thermal management system 200 may be configured to permit selective and independent deactivation of networks 206, 208, 210, 212, 214, 216, 218, thermal management system 200 provides the added benefit of being able to select (via processing unit 400) which exterior segments of aircraft 100, e.g., skin 112, are to be heated using the heat generated by avionics 300. As such, thermal management system 200 enables continuous (or spontaneous) manipulation of the infrared signature of aircraft 100 during flight by selecting to deactivate some network(s) 206, 208, 210, 212, 214, 216, 218 without selecting to deactivate other network(s) 206, 208, 210, 212, 214, 216, 218. For example, in one possible sequence, processing unit 400 may deactivate second network 208, fourth network 212, sixth network 216, and seventh network 218 such that the heat from avionics 300 is transferred only to first network 206, third network 210, and fifth network 214, thereby heating only suction side 124 of first wing 104, suction side 124 of second wing 106, and top 126 of fuselage 102 in order to facilitate increasing the temperature of the infrared signature of aircraft 100 when viewed from above and decreasing the temperature of the infrared signature of aircraft 100 when viewed from below, thereby camouflaging aircraft 100 such that aircraft 100 has an infrared signature that is more in line with a desired lower-altitude backdrop, e.g., land and/or sea.

Alternatively, in another possible sequence, processing unit 400 may repeatedly deactivate one or more networks 206, 208, 210, 212, 214, 216, 218 on a periodic or random time interval in order to render the infrared signature less discernible as being that of an aircraft. For example, processing unit 400 may repeatedly alternate between the following states on a random time interval: (1) simultaneously deactivating third network 210, fourth network 212, fifth network 214, and sixth network 216; and (2) simultaneously deactivating first network 206, second network 208, fifth network 214, and sixth network 216. In this example, the infrared signature of aircraft 100 during flight would fluctuate randomly between the first state (during which only pressure side 122 and suction side 124 of first wing 104 would be heated using heat from avionics 300) and the second state (during which only pressure side 122 and suction side 124 of second wing 106 would be heated using heat from avionics 300). As such, it would be more difficult to detect the infrared signature as being that of an aircraft.

Being that seventh network 218 is coupled in conductive heat transfer with fuel 144 inside of a fuel tank, a fuel line, or other suitable fuel-containing structure of aircraft 100, at least some heat generated by avionics 300 may also be selectively transferrable to fuel 144 using processing unit 400. In this manner, fuel 144 may be selectively preheated to enhance engine combustion, thereby rendering aircraft 100 more fuel efficient. In one embodiment, seventh network 218 may be coupled to fuel 144 by virtue of at least one heat pipe 204 of seventh network 218 being inserted directly into fuel 144 within a fuel tank and including miniature fins at the location of interfacing with fuel 144 in order to more efficiently transfer heat to fuel 144. In another embodiment, a heat exchanger may be provided along a fuel line to exchange heat between fuel 144 and at least one heat pipe 204 of seventh network 218. Alternatively, at least one heat pipe 204 of seventh network 218 may be integrated into walls of a fuel tank, a fuel line, or other fuel-containing structure to surround fuel 144, rather than being inserted directly into fuel 144. Moreover, if a heat pipe 204 of seventh network 218 was to be inserted directly into fuel 144, the size of heat pipe 204 may be reduced in order to minimize the volume of the fuel-containing structure that is being occupied by heat pipe 204, thereby enabling the fuel-containing structure to house a larger quantity of fuel 144. Notably, thermal management system 200 may also be configured to remove heat from fuel 144 if desired, thereby transferring heat from fuel 144 toward thermal rail 202 along seventh network 218 in order to transfer the heat from fuel 144 to any desirable region of aircraft 100, much like the transfer of heat from avionics 300 described above.

Optionally, in another embodiment, a thermal energy storage element 260 such as, for example, a capacitor or other energy storage buffer may be provided along one or more of networks 206, 208, 210, 212, 214, 216, 218 (or along an eighth network that would be dedicated to transferring heat from the heat source, e.g., avionics 300, to a larger energy storage element) for selectively (and simultaneously) deactivating all of networks 206, 208, 210, 212, 214, 216 and possibly seventh network 218. In this manner, the infrared signature of aircraft 100 may be eliminated altogether. For example, in one sequence, the radiation of heat from aircraft 100 may cease entirely (or at least be reduced) by simultaneously deactivating first network 206, second network 208, third network 210, fourth network 212, fifth network 214, and sixth network 216, diverting all of the heat normally associated with those networks 206, 208, 210, 212, 214, 216 to at least one corresponding thermal energy storage element 260.

In the exemplary embodiment, processing unit 400 suitably includes at least one processor, a memory device coupled to the processor, and at least one input/output (I/O) conduit, wherein the conduit includes at least one I/O channel. As used herein, the term processor is not limited to just those integrated circuits referred to in the art as a computer, but broadly refers to a microcontroller, a microcomputer, a programmable logic controller (PLC), an application specific integrated circuit, and other programmable circuits, and these terms are used interchangeably herein. In the embodiments described herein, the memory device may include, but is not limited to, a computer-readable medium, such as a random access memory (RAM), and a computer-readable non-volatile medium, such as flash memory. Alternatively, a floppy disk, a compact disc-read only memory (CD-ROM), a magneto-optical disk (MOD), and/or a digital versatile disc (DVD) may also be used.

In the embodiments described herein, I/O channels may be associated with, but are not limited to, computer peripherals associated with an operator interface such as a mouse and a keyboard. Alternatively, other computer peripherals may also be used that may include, for example, but not be limited to, a control stick for use by an operator in controlling aircraft 100. Furthermore, in the exemplary embodiment, additional I/O channels may be associated with, but not be limited to, an operator interface monitor or a communications link for remotely controlling aircraft 100 and/or thermal management system 200. Moreover, the processor may process information transmitted from a plurality of electronic devices onboard aircraft 100, including, without limitation, electric heaters 258 (and/or other suitable network deactivation mechanisms) or temperature sensors suitably dispersed throughout aircraft 100. The memory device and the storage devices store and transfer information and instructions to be executed by the processor. The memory device and the storage devices can also be used to store and provide temporary variables, static, i.e., non-volatile and non-changing, information and instructions, or other intermediate information to the processor during execution of instructions by the processor. Instructions that are executed include, but are not limited to, analysis of signals transmitted from electric heaters 258 and/or other suitable network deactivation mechanisms. The execution of sequences of instructions is not limited to any specific combination of hardware circuitry and software instructions.

The above-described embodiments facilitate effectively cooling heat sources onboard an aircraft. The devices, systems, and methods disclosed herein further facilitate cooling the electronic systems of an aircraft, thereby enabling the use of more powerful electronic systems onboard the aircraft. The devices, systems, and methods also facilitate increasing the reliability of functioning heat sources (such as electronic systems) onboard an aircraft by better preventing them from overheating. The embodiments disclosed herein further facilitate cooling heat sources onboard an aircraft using less electricity, thereby being less of an electrical load on the power supply of the aircraft. Additionally, the embodiments facilitate utilizing the undesired heat produced by existing heat sources onboard an aircraft to alter the infrared signature of the aircraft by redistributing the undesired heat to exterior surfaces of the aircraft prior to dissipating the heat from the aircraft, thereby heating the exterior surfaces of the aircraft using less centerline electrical power than would electrically powered heating elements dedicated for use in heating the exterior surfaces of the aircraft. The above-described embodiments also facilitate providing a thermal management system that weighs less, e.g., in the absence of associated ductwork, pumps, larger quantities of liquid coolant, etc., thereby enabling the aircraft to weigh less and be more fuel efficient. The devices, systems, and methods further facilitate improving the fuel efficiency of an aircraft by transferring heat to the fuel in order to preheat the fuel for improving combustion performance.

An exemplary technical effect of the methods, systems, and apparatus described herein includes at least one of: (a) effectively cooling heat sources onboard an aircraft; (b) cooling electronic systems of an aircraft, thereby enabling the use of more powerful electronics onboard the aircraft; (c) increasing the reliability of functioning heat sources (such as electronic systems) onboard an aircraft by better preventing the heat sources from overheating; (d) cooling heat sources onboard an aircraft using less electricity, thereby being less of an electrical load on the power supply of the aircraft; (e) utilizing heat produced by existing heat sources onboard an aircraft to alter an infrared signature of the aircraft by redistributing the heat to exterior surfaces of the aircraft prior to dissipating the heat from the aircraft; (f) providing a thermal management system that weighs less, e.g., in the absence of associated ductwork, pumps, larger quantities of liquid coolant, etc., thereby enabling the aircraft to weigh less and be more fuel efficient; and (g) improving the fuel efficiency of an aircraft by preheating the fuel to facilitate better combustion performance.

Exemplary embodiments of thermal management systems and methods of assembling the same are described above in detail. The systems and methods are not limited to the specific embodiments described herein, but rather, components of the systems and/or steps of the methods may be utilized independently and separately from other components and/or steps described herein. For example, the methods may also be used in combination with other systems and methods, and are not limited to practice with only the aircraft-related systems and methods described herein. Rather, the embodiments may be implemented and utilized in connection with many other applications outside of aviation.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A thermal management system for cooling a heat source onboard an aircraft having a frame and a skin coupled to the frame such that the skin includes a first segment and a second segment, said thermal management system comprising:
a first network of heat pipes coupled in conductive heat transfer with the heat source and the first segment of the skin, said first network of heat pipes configured to heat the first segment of the skin using heat from the heat source; and
a second network of heat pipes coupled in conductive heat transfer with the heat source and the second segment of the skin, said second network of heat pipes configured to heat the second segment of the skin using heat from the heat source, wherein said thermal management system is configured to selectively deactivate said first network of heat pipes and said second network of heat pipes.

2. The thermal management system in accordance with claim 1, wherein the heat source onboard the aircraft is an electronic heat dissipating source, and wherein said thermal management system further comprises a thermal rail coupled in conductive heat transfer with the electronic heat dissipating source, said first network of heat pipes, and said second network of heat pipes.

3. The thermal management system in accordance with claim 1, wherein each of said first network of heat pipes and said second network of heat pipes comprises a plurality of sealed, two-phase capillary heat pipes.

4. The thermal management system in accordance with claim 1, wherein said first network of heat pipes and said second network of heat pipes are integrated into the frame of the aircraft.

5. The thermal management system in accordance with claim 1, wherein the aircraft has a fuel-containing structure, and wherein said thermal management system further comprises a third network of heat pipes coupled in conductive heat transfer with the heat source and fuel inside of the fuel-containing structure.

6. The thermal management system in accordance with claim 5, wherein the fuel-containing structure is a fuel tank, said third network of heat pipes coupled in conductive heat transfer with the fuel tank.

7. The thermal management system in accordance with claim 5, wherein at least one heat pipe of said third network of heat pipes is inserted directly into the fuel inside of the fuel-containing structure.

8. The thermal management system in accordance with claim 7, wherein said at least one heat pipe comprises a plurality of miniature fins configured to interface with the fuel.

9. The thermal management system in accordance with claim 5, further comprising a heat exchanger configured to exchange heat between the fuel and said third network of heat pipes.

10. The thermal management system in accordance with claim 5, wherein at least one heat pipe of said third network of heat pipes is integrated into a wall of the fuel-containing structure.

11. The thermal management system in accordance with claim 1, wherein at least one of said first network of heat pipes and said second network of heat pipes is arranged in a herringbone-type configuration.

12. The thermal management system in accordance with claim 1, further comprising a thermal energy storage element associated with at least one of said first network of heat pipes and said second network of heat pipes.

13. The thermal management system in accordance with claim 1, wherein each of said first network of heat pipes and said second network of heat pipes comprises a variable conductance heat pipe to facilitate the selective deactivation.

14. The thermal management system in accordance with claim 13, further comprising a reservoir of gas in flow communication with said variable conductance heat pipe such that when the gas is heated the associated network of heat pipes is deactivated.

15. The thermal management system in accordance with claim 14, wherein the gas is one of an argon gas and a helium gas.

16. The thermal management system in accordance with claim 14, further comprising an electric heater coupled to said reservoir of gas.

17. The thermal management system in accordance with claim 1, further comprising a processing unit configured to selectively deactivate each of said first network of heat pipes and said second network of heat pipes to alter an infrared signature of the aircraft.

18. An aircraft comprising the thermal management system according to claim 1.

19. A method of assembling a thermal management system for cooling a heat source onboard an aircraft having a frame and a skin coupled to the frame such that the skin includes a first segment and a second segment, said method comprising:
coupling a first network of heat pipes in conductive heat transfer with the heat source and the first segment of the skin, the first network of heat pipes configured to heat the first segment of the skin using heat from the heat source;
coupling a second network of heat pipes in conductive heat transfer with the heat source and the second segment of the skin, the second network of heat pipes configured to heat the second segment of the skin using heat from the heat source; and
coupling a processing unit to the first network of heat pipes and the second network of heat pipes, the processing unit configured to selectively deactivate the first network of heat pipes and the second network of heat pipes.

20. A thermal management system for cooling a heat source onboard an aircraft having a frame and a skin coupled to the frame, said thermal management system comprising a network of heat pipes configured to transfer heat from the heat source to the skin by conductive heat transfer between adjacent heat pipes.
